(19) United States
(12) Patent Application Publication
(10) Pub. No.: US 2012/0146029 A1
(43) Pub. Date: Jun. 14, 2012

(54) THIN FILM TRANSISTOR ARRAY PANEL

(75) Inventors: Young Joo CHOI, Yongin-si (KR); Woo Geun LEE, Yongin-si (KR); Kap Soo YOON, Seoul (KR); Ki-Won KIM, Suwon-si (KR); Sang Wan JIN, Seoul (KR); Jae Won SONG, Seoul (KR); Zhu Xun, Yongin-si (KR)

(73) Assignee: SAMSUNG ELECTRONICS CO., LTD., Suwon-si (KR)

(21) Appl. No.: 13/185,105

(22) Filed: Jul. 18, 2011

(30) Foreign Application Priority Data
Dec. 8, 2010 (KR) 10-2010-0124956

(51) Int. Cl. H01L 29/786

(52) U.S. Cl. 257/59; 257/E29.289

(57) ABSTRACT

A thin film transistor array panel includes an insulating substrate, a gate line disposed on the insulating substrate having a gate electrode, a first gate insulating layer disposed on the gate line and made of silicon nitride, a second gate insulating layer disposed on the first gate insulating layer and made of silicon oxide, an oxide semiconductor disposed on the second gate insulating layer, a data line disposed on the oxide semiconductor and having a source electrode, a drain electrode disposed on the oxide semiconductor and facing the source electrode, and a pixel electrode that is connected to the drain electrode. A thickness of the second gate insulating layer may range from 200 Å to less than 500 Å.

### CROSS-REFERENCE TO RELATED APPLICATION

This application claims priority from and the benefit of Korean Patent Application No. 10-2010-0124956, filed on Dec. 8, 2010, which is hereby incorporated by reference for all purposes as if fully set forth herein.

### BACKGROUND OF THE INVENTION

1. Field of the Invention

Exemplary embodiments of the present invention relate to a thin film transistor array panel. More particularly, the present invention relates to a thin film transistor array panel having an oxide semiconductor.

2. Discussion of the Background

A thin film transistor (TFT) may be used as a switching element for independently driving pixels in a flat panel display, e.g., a liquid crystal display or an organic light emitting diode display. A thin film transistor array panel in the flat panel display may include the thin film transistor, a pixel electrode connected to the thin film transistor, a gate line to transmit a gate signal to the thin film transistor, and a data line to transmit a data signal.

The thin film transistor may include a gate electrode connected to the gate line, a source electrode connected to the data line, a drain electrode connected to the pixel electrode, and a semiconductor layer disposed on the gate electrode and between the source electrode and drain electrode to form a channel of the thin film transistor. A data signal may be transmitted to the pixel electrode from the data line according to the gate signal from the gate line. The semiconductor layer of the thin film transistor may be formed of a polysilicon, an amorphous silicon, or an oxide semiconductor.

The semiconductor layer may be formed of oxide semiconductor so that the gate insulating layer has double layers. A gate insulating layer that contacts the oxide semiconductor may be formed of a silicon oxide.

As compared to a silicon nitride layer processing time, a relatively thick silicon oxide layer may have a slow CVD deposition rate and may be processed by dry etching, which may result in a lengthy processing time.

### SUMMARY OF THE INVENTION

Exemplary embodiments of the present invention provide a thin film transistor having a slim profile silicon oxide layer.

Exemplary embodiments of present invention also provide for facile production time of a thin film transistor array panel without deterioration of characteristics of a thin film transistor.

An exemplary embodiment of the present invention discloses a thin film transistor array panel that comprises a substrate, a gate line disposed on the substrate and comprising a gate electrode, a first gate insulating layer disposed on the gate line and comprising silicon nitride, a second gate insulating layer disposed on the first gate insulating layer and comprising silicon oxide, an oxide semiconductor disposed on the second gate insulating layer, a data line disposed on the oxide semiconductor and comprising a source electrode, a drain electrode disposed on the oxide semiconductor and facing the source electrode, and a pixel electrode that is connected to the drain electrode. A thickness of the second gate insulating layer is greater than or equal to 200 Å and less than 500 Å.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a layout view of a thin film transistor array panel according to a first exemplary embodiment of the present invention.

FIG. 2 is a cross-sectional view that is taken along line II-II of FIG. 1.

FIG. 3 is a layout view of a thin film transistor array panel according to a second exemplary embodiment of the present invention.

FIG. 4 is a cross-sectional view that is taken along line IV-IV of FIG. 3.

FIG. 5 is a graph showing characteristics of thin film transistors according to Example 1, Example 2, Comparative Example 1, Comparative Example 2, Comparative Example 3, and Comparative Example 4.

FIG. 6 is a graph showing electric characteristics of thin film transistors according to Example 3 and Comparative Example 1.

FIG. 7 is a graph showing a Id-Vd curve of thin film transistors according to Example 3 and Comparative Example 1.

FIG. 8 is a graph showing an output curve of thin film transistors according to Example 3 and Comparative Example 1.

FIG. 9 is a graph showing NBIS characteristics of thin film transistors according to Example 3 and Comparative Example 1.

FIG. 10 is a graph showing Von driving characteristics for liquid crystal panels that include thin film transistor array panels according to Example 3 and Comparative Example 1.

FIG. 11 is a graph showing a luminance changes for liquid crystal panels that include thin film transistor array panels according to Example 3 and Comparative Example 1.

### DETAILED DESCRIPTION OF THE ILLUSTRATED EMBODIMENTS

The invention is described more fully hereinafter with reference to the accompanying drawings in which embodiments of the invention are shown. This invention may, however, be embodied in many different forms and should not be construed as limited to the embodiments set forth herein. Rather, these embodiments are provided so that this disclosure is thorough and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on,” “connected to,” or “coupled to” another element or layer, it can be directly on, directly connected to, directly coupled to the other element or layer, or intervening elements or layers may be present. In contrast, when an element is referred to as being “directly on,” “directly connected to,” or “directly coupled to” another element or layer, there are no intervening elements or layers present.

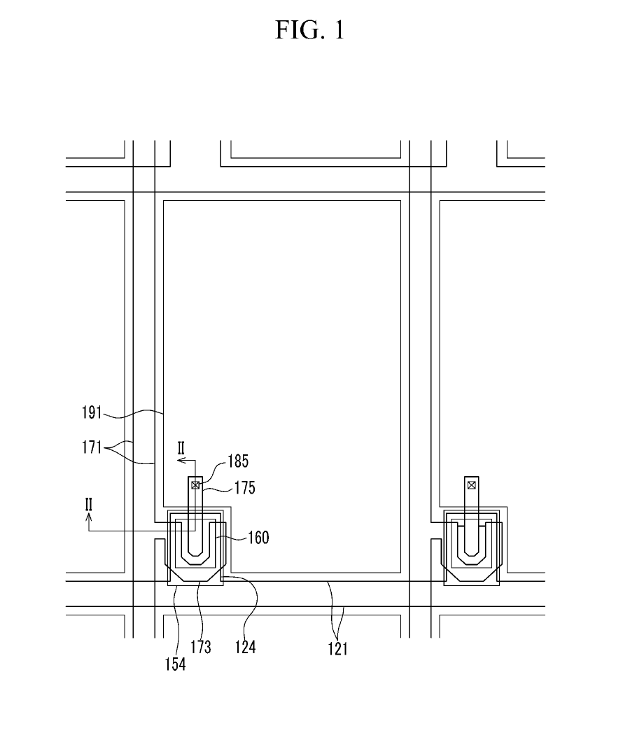

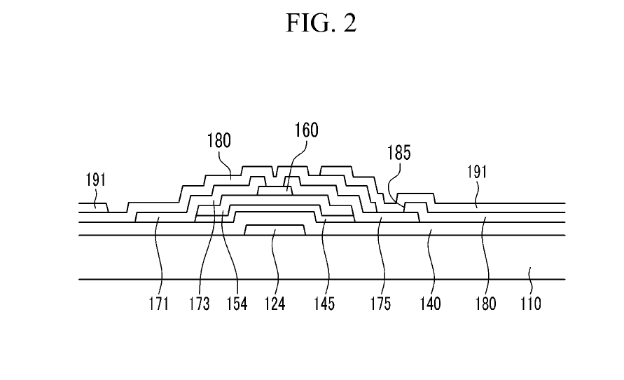

FIG. 1 is a layout view showing a thin film transistor array panel according to an exemplary embodiment of the present invention, and FIG. 2 is a cross-sectional view taken along line II-II of FIG. 1.

As shown in FIG. 1 and FIG. 2, a plurality of gate lines 121 that transmits a gate signal are formed on an insulating substrate 110 that may be made of a transparent glass or plastic. The gate line 121 extends in a horizontal direction and includes a gate electrode 124.

The first gate insulating layer 140 is formed on the gate line 121. The first gate insulating layer 140 may contain a silicon nitride (SiNx), and the thickness of the first gate insulating layer 140 may range from 2000 Å to 5000 Å.

The second gate insulating layer 145 is formed on the first gate insulating layer 140. The second gate insulating layer 145 is formed of silicon oxide (SiOx). The second gate insulating layer 145 may have a thickness that is greater than or equal to and less than 500 Å.

On the second gate insulating layer 145, an oxide semiconductor 154 is formed. The oxide semiconductor 154 is formed on the portion that corresponds to the gate electrode 124 and has an island shape. The oxide semiconductor 154 and the second gate insulating layer 145 have the same planar shape and the same boundary.

The oxide semiconductor 154 may include oxides of zinc (Zn), gallium (Ga), tin (Sn), or indium (In)) or may include more complex oxides, e.g., indium gallium zinc oxide (InGaZnO₄), zinc indium oxide (ZnInO), or zinc tin oxide (ZnSnO).

A plurality of data lines 171 and a plurality of drain electrodes 175 are formed on the oxide semiconductor 154 and the first gate insulating layer 140.

The data line 171 extends in a vertical direction, crosses the gate line 121, and transmits data voltage. Each of data lines 171 includes a plurality of a source electrode 173 extending toward the drain electrode 175. As a pair, the source electrode 173 and the drain electrode 175 are separated from each other and face each other with respect to the gate electrode 124.

The gate electrode 124, source electrode 173, and drain electrode 175 form a thin film transistor (TFT) in conjunction with the oxide semiconductor 154, and a channel of the thin film transistor is formed in the oxide semiconductor 154 between the source electrode 173 and drain electrode 175.

A channel passivation layer 160 that protects the TFT channel is formed on the channel of the thin film transistor. The channel passivation layer 160 may contain a silicon oxide (SiOx).

A passivation layer 180 that has a contact hole 185 is formed on the first gate insulating layer 140, data line 171, drain electrode 175, and channel passivation layer 160, and a pixel electrode 191 that is connected to the drain electrode 175 through the contact hole 185 is formed on the passivation layer 180. Herein, the passivation layer 180 may be formed from a silicon nitride (SiNx).

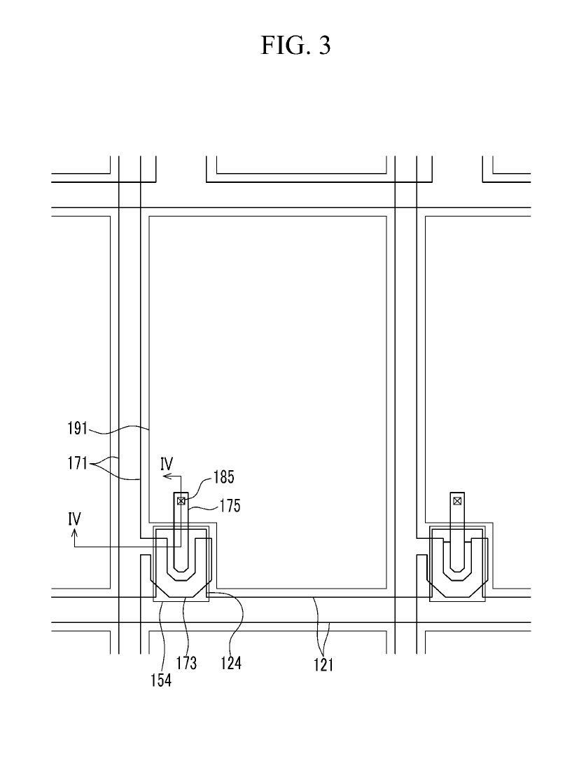

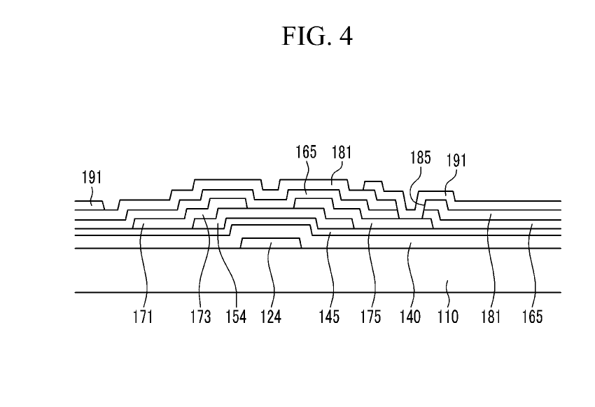

Next, referring to FIG. 3 and FIG. 4, a second exemplary embodiment of the present invention is described.

FIG. 3 is a layout view showing a thin film transistor array panel according to the second exemplary embodiment of the present invention, and FIG. 4 is a cross-sectional view taken along line IV-IV FIG. 3.

As shown in FIG. 3 and FIG. 4, the thin film transistor array panel according to the second exemplary embodiment of the present invention has a structure in which the structures of the second gate insulating layer 145 and the first passivation layer 165 are different from each other, and the remaining structure is the same or similar as the structure of the thin film transistor array panel according to the first exemplary embodiment.

The gate line 121 includes the gate electrode 124 and is formed on the insulating substrate 110 that may be made of a transparent glass or plastic. The first gate insulating layer 140 may be made a silicon nitride (SiNx) with a thickness ranging from 2000 Å to 5000 Å and is formed on the gate line 121.

The second gate insulating layer 145 is formed on the first gate insulating layer 140. The second gate insulating layer 145 may be made of a silicon oxide (SiOx) with thickness that may be greater than or equal to 200 Å and less than 500 Å. The second gate insulating layer 145 may be disposed on an entire surface of the first gate insulating layer 140.

On the second gate insulating layer 145, an oxide semiconductor 154 is formed. The oxide semiconductor 154 is formed on a portion that corresponds to the gate electrode 124 and may have an island shape.

The oxide semiconductor 154 may include oxides of zinc (Zn), gallium (Ga), tin (Sn) or indium (In) or may include more complex oxides such as indium gallium zinc oxide (InGaZnO₄), indium zinc oxide (Zn—In—O), or zinc tin oxide (Zn—Sn—O).

A plurality of data lines 171 and a plurality of drain electrodes 175 are formed on the oxide semiconductor 154 and the first gate insulating layer 140.

The data line 171 extends in a vertical direction, crosses the gate line 121, and transmits data voltage. The data line 171 includes a source electrode 173 extending toward the drain electrode 175. In a pair, the source electrode 173 and the drain electrode 175 are separated from each other and faces each other with respect to the gate electrode 124.

The gate electrode 124, source electrode 173, and drain electrode 175 form a thin film transistor (TFT) in conjunction with the oxide semiconductor 154, and a channel of the thin film transistor is formed in the oxide semiconductor 154 between the source electrode 173 and drain electrode 175.

The first passivation layer 165 may be made of a silicon oxide (SiOx) and is formed on the second gate insulating layer 145, data line 171, drain electrode 175 and the channel of the thin film transistor. The second passivation layer 181 may be made of a silicon nitride (SiNx) and formed on the first passivation layer 165. The first passivation layer 165 and the second passivation layer 181 include a contact hole 185 that exposes the drain electrode 175.

The pixel electrode 191 is connected to the drain electrode 175 through the contact hole 185 and is formed on the second passivation layer 181.

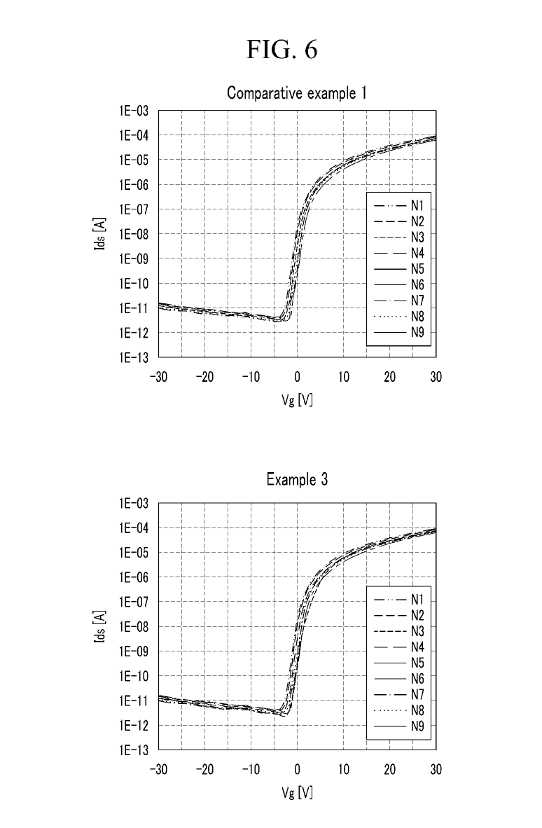

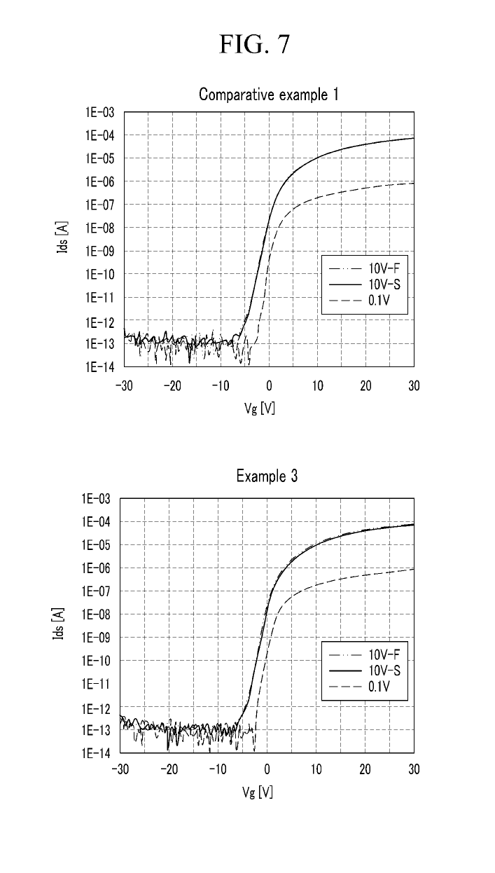

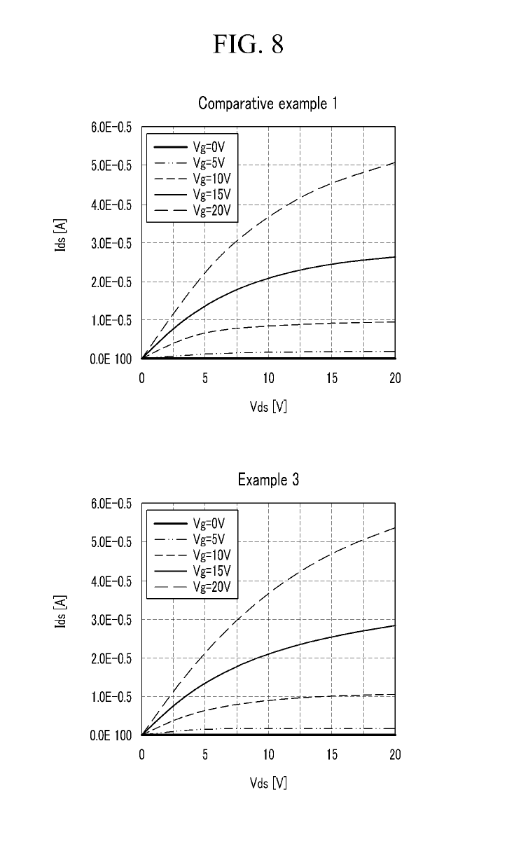

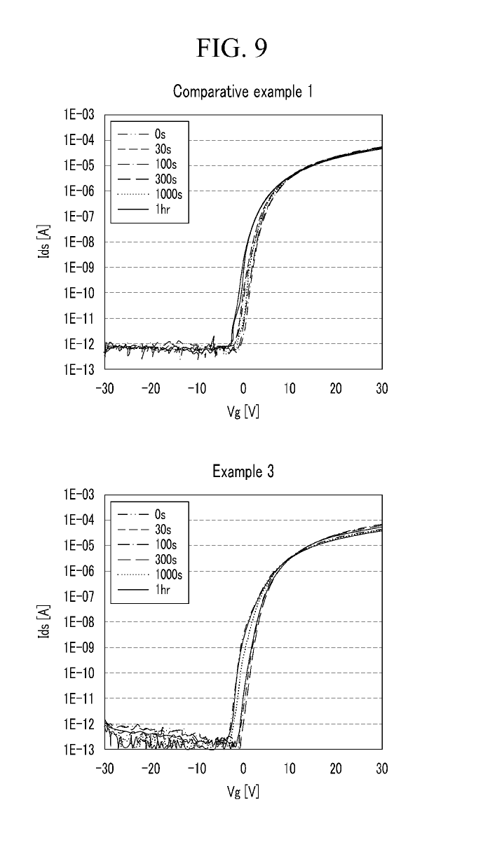

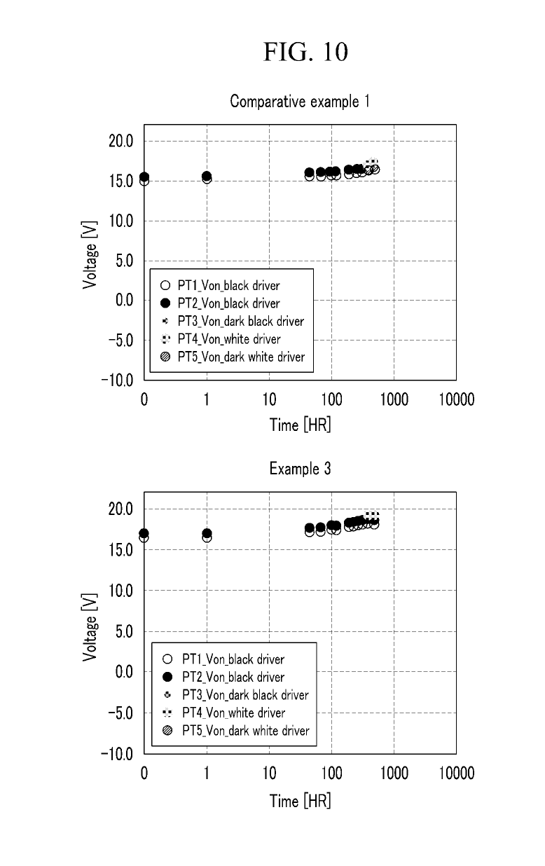

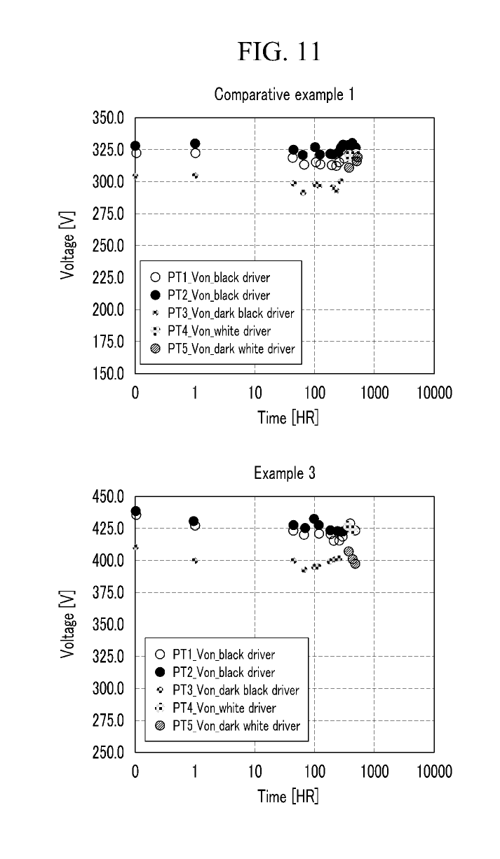

Next, characteristics of the thin film transistor array panel according to several Examples that correspond to exemplary embodiments of the present invention and thin film transistor array panels according to comparative examples will be described with reference to FIG. 6, FIG. 7, FIG. 8, FIG. 9, FIG. 10, and FIG. 11.

In the thin film transistor array panel according to Example 1, the thickness of the first gate insulating layer that is made of silicon nitride (SiNx) is 4000 Å, and the thickness of the second gate insulating layer that is made of silicon oxide (SiOx) is 300 Å.

In the thin film transistor array panel according to Example 2, the thickness of the first gate insulating layer that is made of silicon nitride (SiNx) is 4000 Å, and the thickness of the second gate insulating layer that is made of silicon oxide (SiOx) is 200 Å.

In the thin film transistor array panel according to Comparative Example 1, the thickness of the first gate insulating layer that is made of silicon nitride (SiNx) is 4000 Å, and the thickness of the second gate insulating layer that is made of silicon oxide (SiOx) is 500 Å.

In the thin film transistor array panel according to Comparative Example 2, the thickness of the first gate insulating layer that is made of silicon nitride (SiNx) is 4000 Å, and the thickness of the second gate insulating layer that is made of silicon oxide (SiOx) is 100 Å.

In the thin film transistor array panel according to Comparative Example 3, the thickness of the first gate insulating layer that is made of silicon nitride (SiNx) is 4000 Å, and the thickness of the second gate insulating layer that is made of silicon oxide (SiOx) is 50 Å.

In the thin film transistor array panel according to Comparative Example 4, the gate insulating layer is formed of only silicon nitride (SiNx) with a thickness of 4000 Å.

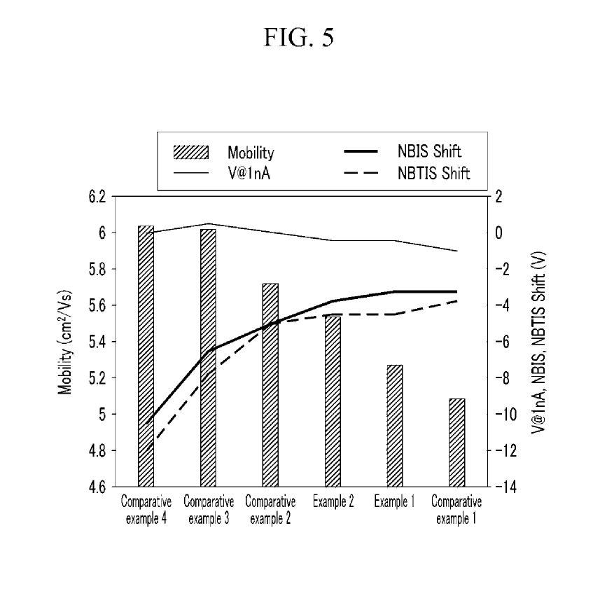

FIG. 5 is a graph showing characteristics of thin film transistors according to Example 1, Example 2, Comparative Example 1, Comparative Example 2, Comparative Example 3, and Comparative Example 4.

As shown in FIG. 5, a mobility, voltage V (at 1 nA), negative bias illumination stress (NBIS), and negative bias temperature illumination stress (NBTIS) characteristics are compared.

In the case of the mobility, as the thickness of the second gate insulating layer increases, the mobility is decreases. Since the mobility change is within 1.0 cm²/Vs, there is little difference between the mobility according to the thickness of the second gate insulating layer. In addition, in the case of voltage V (at 1 nA), there is little difference between the mobility according to the thickness of the second gate insulating layer.

NBIS is a metric for the operational characteristic of a thin film transistor in terms of a voltage shift for current to flow between the drain and source electrodes when light is irradiated to the thin film transistor by a light source such as backlight at room temperature. NBTIS is a metric for the operational characteristic of a thin film transistor in terms of a voltage shift for current to flow between the drain and source electrodes when light is irradiated to the thin film transistor by a light source such as backlight at 60° C.

If NBIS is −4 V or more and NBTIS is −5 V or more, there is no degradation in the thin film transistor. That is, for no thin film transistor degradation, the voltage shifts for NBIS should range between −4 V to 0 V and for NBTIS should range from −5 V to 0 V.

In the case of the thin film transistor array panels according to Comparative Example 1, Example 1, and Example 2, NBIS is −4 V or more and NBTI is −5 V or more, and in the case of Comparative Example 2, Comparative Example 3, and Comparative Example 4, NBIS is less than −4 V and NBTI is less than −5 V. That is, in the case where the thickness of the second insulating layer is 200 Å or more, there is no degradation in the thin film transistor.

As described above, in the case where the thickness of the second gate insulating layer that may be made of silicon oxide (SiOx) is 200 Å or more, changes to the electrical characteristics of the thin film transistor is not large.

The characteristic of the thin film transistor array panel in which the thickness of the second gate insulating layer that is formed of silicon oxide (SiOx) may be 300 Å or more. Characteristics of the thin film transistor array panel with the thickness of the second gate insulating layer that may be made of silicon oxide (SiOx) of 500 Å is described below with reference to FIG. 6, FIG. 7, FIG. 8, FIG. 9, FIG. 10, and FIG. 11.

FIG. 6, FIG. 7, FIG. 8, FIG. 9, FIG. 10, and FIG. 11 are graphs showing characteristics of the thin film transistor array panel according to Example 3 and the thin film transistor array panel according to Comparative Example 1.

In the thin film transistor array panel according to Example 3, the thickness of the first gate insulating layer that is formed of silicon nitride (SiNx) is 4200 Å, and the thickness of the second gate insulating layer that is formed of silicon oxide (SiOx) is 300 Å. Therefore, the thickness of the second gate insulating layer of Example 3 is the same as that of Example 1.

That is, the sum totals of the thicknesses of the first gate insulating layer and the second gate insulating layer of the thin film transistor array panel according to Example 3 and the thin film transistor array panel according to Comparative Example 1 are the same as each other.

FIG. 6 is a graph showing electrical characteristics based on electrical die sorting (EDS) probing of the thin film transistor according to Example 3 and the thin film transistor according to Comparative Example 1.

The measurement was performed at 9 positions of the thin film transistor array panel according to Example 3 and the thin film transistor array panel according to Comparative Example 1. Data was acquired for a number of samples shown in the legend of the graphs as N1, N2, N3, N4, N5, N6, N7, N8, and N9.

In the case of Comparative Example 1, when Vg is 0 V, Ids approaches 100 pA (1E-10 A) at most positions. When Vg is 10 V, Ids approaches 10 μA (1E-05 A) at most positions. When Vg is −20 V, Ids approaches 10 pA (1E-11 A) at most positions.

In the case of Example 3, when Vg is 0 V, Ids approaches 100 pA (1E-10 A) at is most positions, when Vg is 10 V, Ids approaches 10 μA (1E-05A) at most positions. When Vg is −20 V, Ids approaches 10 pA (1E-11A) at most positions.

That is, it can be seen that when Comparative Example and Example 3 are compared to each other, their EDS characteristics are similar.

FIG. 7 is a graph showing a Vg-Ids curve of the thin film transistor according to Example 3 and the thin film transistor according to Comparative Example 1.

Vg and Ids were measured by applying 10 V and 0.1 V to the source and drain electrodes. Application of 10 V occurred twice, labeled as 10V-F and 10V-S for the first and second times, respectively.

In the case of Comparative Example 1 and Example 3, when 10 V was applied first (10V-F) and when 10 V was applied second (10V-S), Ids values were nearly constant for −30 V<Vg<30 V.

In addition, in the case of Comparative Example 1 and Example 3, when 10 V was applied, Ids was about 10 nA (1E-08 A) if Vg was 0 V. When 0.1 V is applied, Ids nears 100 pa (1E-10A) with Vg=0 V.

As described above, the Vg-Ids curves of Comparative Example 1 and Example 3 are almost similar to each other.

FIG. 8 is a graph showing output curves of the thin film transistor according to Example 3 and the thin film transistor according to Comparative Example 1.

When Vg of 0 V, 5 V, 10 V, 15 V and 20 V was applied, Vds and Ids were measured. For Vg of 0 V, 5 V, 10 V, 15 V and 20 V, the output curves are similar to each other.

FIG. 9 is a graph showing negative bias illumination stress (NBIS) characteristics of the thin film transistor according to Example 3 and the thin film transistor according to is Comparative Example 1.

Vg and Ids were measured by irradiating light for 0 sec, 30 sec, 100 sec, 300 sec, 1000 sec, and 1 hour. In the case of Comparative Example 1, for Ids=1 nA, the voltage change ΔV was −2.0 V between 0 sec and 1 hour illumination times, and in the case of Example 3, for Ids=1 nA, a larger voltage change of ΔV=−2.75 V was observed.

When Comparative Example 1 and Example 3 are compared to each other, when Ids=1 nA, there is a difference of −0.75 V in the voltage change ΔV (i.e., the difference between −2.0V and −2.75V). When Ids is 1 nA, if the voltage change ΔV is −3.0 or greater, NBIS characteristics of Comparative Example 1 and Example 3 have a desirable level.

FIG. 10 is a graph showing Von driving characteristics of a liquid crystal panel that includes thin film transistor array panels according to Example 3 and Comparative Example 1.

The liquid crystal panel was driven to display a black screen (Black driver), a white screen (White driver), and a grey screen (Dark black driver, Dark white driver) at 5 positions, and the Von driving characteristics of Comparative Example 1 and Example 3 are almost similar to each other for these various driving conditions.

FIG. 11 is a graph showing a luminance change of a liquid crystal panel that includes thin film transistor array panels according to Example 3 and Comparative Example 1.

The liquid crystal panel was driven to display a black screen, a white screen, and a grey screen at 5 positions, and the luminance changes of Comparative Example 1 and Example 3 are similar to each other.

As described above, with reference to FIG. 5, FIG. 6, FIG. 7, FIG. 8, FIG. 9, FIG. 10, and FIG. 11, when the characteristics of the thin film transistor array panels according to Example 1, Example 2, and Example 3 of the present invention and the thin film transistor array panel according to Comparative Example 1 are compared with each other, the characteristics of the thin film transistor array panels according to Example 1, Example 2, and Example 3 of the present invention and the thin film transistor array panel according to Comparative Example 1 are similar to each other.

Although exemplary embodiments described above and shown in various figures include bottom gate thin film transistors, the present invention is not limited thereto, and top gate thin film transistors may also be used. Moreover, the present invention is not limited to thin film transistors driving pixels. As such, the present invention and its exemplary embodiments may be applied to thin film transistors in gate and date driver circuits.

It will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

What is claimed is:

1. A thin film transistor array panel, comprising:
a substrate;
a gate line disposed on the substrate and comprising a gate electrode;
a first gate insulating layer disposed on the gate line and comprising silicon nitride;
a second gate insulating layer disposed on the first gate insulating layer and comprising silicon oxide;
an oxide semiconductor disposed on the second gate insulating layer;
a data line disposed on the oxide semiconductor and comprising a source electrode;
a drain electrode disposed on the oxide semiconductor and facing the source electrode; and
a pixel electrode that is connected to the drain electrode,
wherein a thickness of the second gate insulating layer is greater than or equal to 200 Å and less than 500 Å.

2. The thin film transistor array panel of claim 1, wherein a thickness of the second gate insulating layer is 300 Å.

3. The thin film transistor array panel of claim 2, wherein a thickness of the first gate insulating layer ranges from 2000 Å to 5000 Å.

4. The thin film transistor array panel of claim 3, wherein planar shapes and boundaries of the second gate insulating layer and the oxide semiconductor are the same as each other.

5. The thin film transistor array panel of claim 4, further comprising a channel passivation layer disposed on an exposed portion of the oxide semiconductor between the source electrode and the drain electrode.

6. The thin film transistor array panel of claim 5, further comprising a passivation layer disposed on the channel passivation layer.

7. The thin film transistor array panel of claim 6, wherein the channel passivation layer comprises silicon oxide, and the passivation layer comprises silicon nitride.

8. The thin film transistor array panel of claim 3, wherein the second gate insulating layer is disposed on an entire surface of the first gate insulating layer.

9. The thin film transistor array panel of claim 8, further comprising a first passivation layer disposed on the source electrode, the drain electrode, and an exposed oxide portion of the oxide semiconductor between the source electrode and drain electrode

10. The thin film transistor array panel of claim 9, further comprising a second passivation layer disposed on the first passivation layer.

11. The thin film transistor array panel of claim 10, wherein the first passivation layer comprises silicon oxide, and the second passivation layer comprises silicon nitride.

12. The thin film transistor array panel of claim 1, wherein the oxide semiconductor comprises at least one of an oxide of zinc, an oxide of gallium, an oxide of tin, an oxide of indium, zinc oxide (ZnO), indium gallium zinc oxide (InGaZnO₄), indium zinc oxide (InZnO), or zinc tin oxide (ZnSnO), and mixtures thereof.
